(19) United States
(12) Patent Application Publication
(10) Pub. No.: US 2025/0121350 A1
(43) Pub. Date: Apr. 17, 2025

(54) METHODS OF PROCESSING OLIVINE MATERIALS

(71) Applicant: Project Vesta, PBC, San Francisco, CA (US)

(72) Inventors: Geoffrey W. CALKINS, San Francisco, CA (US); Devon Barnes COLE, San Francisco, CA (US); Douglas O. EDWARDS, Denver, CO (US); Stephan Wilhelm Maria KIRSCH, Stirling (AU); Stephen J. ROMANIELLO, Knoxville, TN (US); Brian D. LEY, Hawi, HI (US); Margaret G. ANDREWS, Montclair, NJ (US); Nathan G. WALWORTH, Los Angeles, CA (US); Thomas ISHOEY, San Diego, CA (US); Francesc MONTSERRAT, Cappelle aan den Ussel (NL); Chloe S. LEACH, Collingham (GB); David L. KRIEBEL, Kennett Square, PA (US); Tom C. GREEN, San Francisco, CA (US)

(21) Appl. No.: 18/658,811

(22) Filed: May 8, 2024

Related U.S. Application Data
(60) Provisional application No. 63/501,096, filed on May 9, 2023.

(51) Int. Cl. B01J 20/10; B01J 20/28; B01J 20/30; C01B 33/22; G06F 30/28

(52) U.S. Cl. CPC B01J 20/10; B01J 20/28004; B01J 20/28016; B01J 20/3021; C01B 33/22; G06F 30/28; C01P 2004/60

(57) ABSTRACT

The present disclosure provides methods and systems for processing of ultramafic materials. The ultramafic materials may comprise olivine. The methods and systems described herein may include a high-pressure grinding roll (HPGR) to process the ultramafic materials. The processed ultramafic materials may be added to an aqueous solution to increase an alkalinity of the solution. The processed ultramafic materials may capture carbon dioxide (e.g., atmospheric carbon dioxide.)

### CROSS-REFERENCE

This application claims the benefit of U.S. Provisional Application Ser. No. 63/501,096, filed May 9, 2023, which is entirely incorporated herein by reference.

### BACKGROUND

There exists a need for compositions to capture dissolved carbon dioxide within aqueous environments. Additionally, improving the rate of dissolution of materials that enable carbon sequestration will increase a total rate and amount of carbon sequestration from these materials.

### SUMMARY

High pressure grinding roll (HPGR) is a grinding technology that may be used in minerals and cement processing. Relative to traditional grinding technologies, HPGRs have a number of advantages, including lower energy consumption, lower maintenance costs, smaller footprint, and the potential to create microcracking, which can be advantageous in certain applications.

Disclosed herein is a high-pressure grinding roll (HPGR) based system for processing a feed material for the purpose of carbon capture. This system may consist of one or more of several components that affect a property (e.g., particle size) of a composition of the feed material (e.g., olivine).

Another aspect of the present disclosure provides a non-transitory computer readable medium comprising machine executable code that, upon execution by one or more computer processors, implements any of the methods above or elsewhere herein.

Another aspect of the present disclosure provides a system comprising one or more computer processors and computer memory coupled thereto. The computer memory comprises machine executable code that, upon execution by the one or more computer processors, implements any of the methods above or elsewhere herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Whenever the term “at least,” “greater than,” or “greater than or equal to” precedes the first numerical value in a series of two or more numerical values, the term “at least” or “greater than” applies to each one of the numerical values in that series of numerical values.

Whenever the term “no more than,” “less than,” or “less than or equal to” precedes the first numerical value in a series of two or more numerical values, the term “no more than” or “less than” applies to each one of the numerical values in that series of numerical values.

The term “about” or “nearly” as used herein generally refers to within (plus or minus) 15%, 10%, 9%, 8%, 7%, 6%, 5%, 4%, 3%, 2%, or 1% of a designated value.

As used herein, the singular forms “a”, “an”, and “the” include plural references unless the context clearly dictates otherwise.

In one aspect, the present disclosure provides a system for processing a feed material. The material may be used in a process or system for carbon capture. The material may be an ultra-mafic material (e.g., olivine). In some cases, the system may comprise, or be based upon, a high-pressure grinding roll (HPGR). In some cases, the system may further comprise one or more of an air classifier, a cyclone, and a bag house filter.

In some embodiments, the system may comprise an air classifier. The air classifier may be a gravitational, gravitational inertial, centrifugal, cyclonic, gyrotor, or portable air classifier. The air classifier may use air flow, gravity, and/or sharp directional changes to separate material based on size. For example, the air classifier may separate material with a particle size from about 5 mm to about 150 micrometers (microns). In some instances, the classifier may separate particles into two or more, three or more, four or more, five or more, seven or more, or ten or more groups with different particle sizes. Upper and/or lower particle size ranges for any of the groups may be about 50 microns, 100 microns, 150 microns, 200 microns, 250 microns, 300 microns, 500 microns, 1 mm, 1.5 mm, 2 mm, 3 mm, 4 mm, 5 mm, 7 mm, 10 mm, or any other value.

The system may comprise a cyclone component. The cyclonic component may separate one or more particle groups from a material stream. The cyclone component may receive a two phase material stream, where one phase is a fluid stream (e.g., air) and a second phase is a solid (e.g., particulates). The cyclone component may receive a fluid stream and solid particulates as a combined material stream, and separate the fluid from the particulates. The cyclone component may be designed to allow the larger particulates to fall towards a bottom opening of the cyclone due to a gravitational force. The cyclone component may be designed to discharge the fluid stream towards an opposite (e.g., upward) opening of the cyclone. The cyclone may separate larger particles from the material stream. In some cases, the cyclone may separate particles that have a particle size of at least about 5 microns, 10 microns, 20 microns, 50 microns, 100 microns, 200 microns, 300 microns, 500 microns, 1 mm, 1.5 mm, 2 mm, 3 mm, 4 mm, 5 mm, 7 mm, 10 mm, or any other value.

In some embodiments, the system may comprise a bag house filter. The bag house filter may filter out particles of a smaller size, (e.g., particles that pass through the bag filter) while allowing larger particles (e.g., particles that do not pass through the bag filter) to be directed to additional components to be further processed. Any particles having a size smaller than any of the values describe elsewhere herein may be filtered out.

The system may process a feed material. The feed material may be olivine or another mineral with carbon capture potential (e.g., an ultramafic material). The feed material may be processed by the system into particles with a smaller average particle size and/or a larger surface area. The larger surface area may improve the carbon capture potential of the material and/or increase the speed at which the carbon capture process occurs when facilitated by the material with a larger surface area. In some cases, the system described herein may increase the surface area of the feed material such that a ratio of surface area of the feed material to the surface area of the material after processing through the system may be equal to or greater than 2:3, 1:2, 1:3, 1:4, 1:5, 1:7, 1:10, 1:15, 1:20, 1:30, 1:50, 1:100, 1:500, 1:1000, or greater.

The system described herein may crush the feed material to produce one or more improved characteristics of the processed material that increase a rate of dissolution of the material in a carbon capture environment. These characteristics may include a particle size distribution of the processed material, microcracks withing the processed material, particles with an edged or angular particle shape, improved porewater flow properties, improved dissolution within aqueous environments. One or more of these improved characteristics may be produced by the system design parameters. One or more of these improved characteristics may combine to produce other beneficial properties of the final processed material. The final product will have improved utility on the basis of one or more of the following characteristics.

The processed material may have a particle size distribution (PSD) that optimizes dissolution. Alternatively, or in addition, the particle size distribution may comply with regulatory requirements. The regulatory requirements may optionally be defined by a governing authority, which may include a national, state, provincial, or local governing authority. In some cases, the particle size distribution may have a minimum particle size of at least about 5 microns (um), 10 um, 50 um, 100 um, 500 um, 1 millimeter (mm), 5 mm, 10 mm, 50 mm, 100 mm, 500 mm, or greater. In some instances, the particle size distribution may include a desired particle range (e.g., between minimum and maximum size), which may be less than or equal to about 500 mm, 300 mm, 200 mm, 100 mm, 75 mm, 50 mm, 30 mm, 10 mm, 5 mm, 3 mm, 2 mm, 1 mm, 500 microns, 300 microns 200 microns, 100 microns, 50 microns, 20 microns, 10 microns, or 5 microns. In some cases, the processed material may have a particle size distribution that is within 100%, 75%, 50%, 25%, 10%, 5% or less of a particle size distribution of a native material composition to a selected target site. The system may be used by a method of selecting a site, running feed material through the system described herein, and producing processed material that has a particle size distribution that is appropriate for the natural composition of the selected site.

The processed material may have a particle size distribution that is narrow. The particle size distribution (PSD) may be measured by its polydispersity index (PDI). The processed material may have a PDI that is greater than or equal to about 1, 1.5, 2, 3, 5, 7, 10, 13, 15, or 20. The processed material may have a PDI that is less than or equal to about 20, 15, 13, 10, 7, 5, 3, 2, 1.5, 1.2 or lower. In some cases, the PDI may be between two values described above, for example between about 5 and 2. A smaller PDI may indicate a more consistent particle size among the processed material which may result in consistent carbon capture rates. This may aid the measuring of an amount of carbon captured, verifying this amount, and generating carbon credits associated with a level of this carbon sequestration activity.

The processed material may have microcracks within particles of the material. Microcracking within particles of the processed material (e.g., product) may allow for improved dissolution. In some instances, microvoids may also be formed. In some instances, one or more surface intrusions may be provided. A number of microcracks per dimension of object (e.g., area) may be at least 1/mm2, 2/mm2, 3/mm2, 5/mm2, 10/mm2, 15/mm2, 20/mm2, 30/mm2, 50/mm2, 100/mm2, 150/mm2, 200/mm2, 300/mm2, 500/mm2, 750/mm2, 1,000/mm2, 5,000/mm2, In some instances, a mean microcrack length may be at least 5 microns, 10 microns, 15 microns, 20 microns, 50 microns, 75 microns, 100 microns, 150 microns, 200 microns, 250 microns, 300 microns, 350 microns, 400 microns, 450 microns, 500 microns, or any other value. Microcracks within the particles may extend in at least 1 dimension. In some instances, the directions of microcracks may extend in at least two or three dimensions. Where a microcrack may extend in at least two or three dimensions, a mean length of a major axis may be at least 5 microns, 10 microns, 15 microns, 20 microns, 50 microns, 75 microns, 100 microns, 150 microns, 200 microns, 250 microns, 300 microns, 350 microns, 400 microns, 450 microns, 500 microns, or any other value. A mean length of a minor axis may be at least 5 microns, 10 microns, 15 microns, 20 microns, 50 microns, 75 microns, 100 microns, 150 microns, 200 microns, 250 microns, 300 microns, 350 microns, 400 microns, 450 microns, 500 microns, or any other value.

In some instances, the processed materials may have pores or voids within the particles. For example, the processed materials may have a porosity of at least 1%, 2%, 3%, 5%, 7%, 10%, 20%, or 30%.

The processed material may have a plurality of particles with an edged or angular particle shape. In some cases, a majority of the processed material may have a particle shape that is edged, angular, sharp, or another shape that has a higher surface area to volume ratio than a sphere. In some cases, an average surface area to volume ratio of the plurality of particles of the processed material may be greater than or equal to about 100:1. 50:1, 25:1, 5:1, 2:1, 1:1, 1:2, 1:5, 110, 1:25, 1:50, 1:100 or greater. The compactness of any cross-section of the particles may be on less than or equal to 0.9, 0.8, 0.7, 0.6, 0.5, 0.4, 0.3, 0.2, or 0.1. The high-pressure grinding roll system may produce these angled particle shapes based on the interactions of particles within the system.

The system may produce a processed material that exhibits improved characteristics for porewater flow and/or dissolution.

The system may produce a processed material that has an increased total product surface area. The total surface area may be measured in square meters per kilogram of material. The total surface area per unit weight of the processed material may be at least 2 times, 3 times, 5 times, 7 times, 10 times, 15 times, 20 times, 35 times, 50 times, 75 times, 100 times, 200 times, 300 times, 500 times or greater than the surface area per unit weight of the feed material. Producing a processed material (e.g., product) with a consistent, increased surface to volume ratio, or total surface area per unit weight ratio, may allow for controlled weathering of the material (e.g., olivine) within carbon sequestration applications.

Sediment transport models may be based on one or more characteristics of a material. A sediment transport model may be based, at least in part, on a particle size of a material that is modeled. Therefore, controlling a particle size distribution of a processed material may allow for more accurate modeling of sediment transport of that material.

Material with a minimum or maximum particle size may be less difficult to deploy through various methods. For, example, a material with a particle size that is too small may be more easily aerosolized and be lost to waste during open transportation to or through a deployment site. In contrast, a material with a particle size that is too large, may be inefficient at moving through one or more other processed and feed intake subunits such as gravity feeders, conduits, and water stream-based transport. The present system may allow for a narrow particle size distribution (low polydispersity index) around a target particle size for an intended deployment. The system described herein may result in minimized difficulty in ship-or land-based deployment of the processed material (e.g., product).

In order to affect the above characteristics, the system may be designed based on certain parameters, including but not limited to the parameters described herein.

In some bases, one or more parameters of the high-pressure grinding roll system (e.g., pressure, arrangement of grinding rolls, stream flow rates, temperature, etc.) may be dynamically adjusted (e.g., controlled) based on one or more characteristics of the feed material (e.g., mineralogy, chemistry, solid density, bulk density, particle size distribution, and moisture).

In some bases, one or more parameters of the high-pressure grinding roll system (e.g., pressure, arrangement of grinding rolls, stream flow rates, temperature, etc.) may be dynamically adjusted (e.g., controlled) based on one or more characteristics of the deployment site (e.g., ocean chemistry, water temperature, native sediment particle size distribution).

In some bases, one or more parameters of the high-pressure grinding roll system (e.g., pressure, arrangement of grinding rolls, stream flow rates, temperature, etc.) may be dynamically adjusted (e.g., controlled) to comply with one or more regulation on a physical characteristic of the processed material described herein.

In addition, certain characteristics of the HPGR itself, (e.g., grinding force, roll speed, and roll dimensions) or a component of the system downstream or upstream of a high pressure grinding roll (e.g., the air classification system, cyclone, and bag house filter) such as air feed volumes or air feed velocity may be dynamically controlled to produce a preferred processed material.

What is claimed is:

1. A method of processing an ultramafic material comprising:
a. providing said ultramafic material to a system comprising a high-pressure grinding roll (HPGR); and
b. using said system, microcracking said ultramafic material, thereby generating a processed ultramafic material with a greater surface area than said ultramafic material.

2. The method of claim 1, further comprising (c) providing said processed ultramafic material to an aqueous solution to increase an alkalinity of said solution.

3. The method of claim 2, wherein said processed ultramafic material dissolves at a rate that is increased as compared to ultramafic materials that has not been microcracked.

4. The method of claim 1, wherein said ultramafic material comprises olivine.

5. The method of claim 1, further comprising separating one or more particle groups from a material stream comprising said ultramafic material.

6. The method of claim 5, wherein said separating comprises a cyclone component.

7. The method of claim 5, wherein a first particle group of said one or more particle groups has an average particle size of less than or equal to about 1 mm.

8. The method of claim 5, wherein a first particle group of said one or more particle groups has a polydispersity index less than or equal to about 20.

9. The method of claim 1, wherein said processed ultramafic material has at least 10 microcracks per millimeter squared (mm²) of surface area.

10. The method of claim 1, wherein a microcrack in a particle of said processed ultramafic material has a mean length of a major axis of at least 10 microns.

11. The method of claim 1, wherein a particle of said processed ultramafic material may have a surface area to volume ratio greater than or equal to 1:1.

12. The method of claim 1, further comprising controlling, via a controller unit, one or more parameters selected from the group consisting of a pressure of the HPGR, an arrangement of the HPGR, a flow rate of said ultramafic material to said system, and a grinding temperature.

13. The method of claim 12, wherein said controlling said one or more parameters is based at least in part on a characteristic of said ultramafic material.

14. The method of claim 13, wherein said characteristic of said ultramafic material is selected from the group consisting of a mineralogy, a chemistry, a solid density, a bulk density, a particle size distribution, and a moisture of said ultramafic material.

15. The method of claim 13, wherein said characteristic is said mineralogy of said ultramafic material.

16. The method of claim 1, further comprising measuring, modeling, or deriving one or more parameters that directly or indirectly quantifies an amount of carbon dioxide captured by said ultramafic material in said aqueous solution.

17. The method of claim 1, further comprising modeling said dissolution of said ultramafic material based at least in part on a sediment transport model of said ultramafic material.

18. The method of claim 17, wherein said sediment transport model is based at least in part on a measurement collected from a sensor in said aqueous solution.

19. A system for processing an ultramafic material, the system comprising:
a feed stream configured to provide said ultramafic material;
a high pressure grinding roll (HPGR);
a controller configured to control one or more parameters selected from the group consisting of a pressure of the HGPR, an arrangement of the HPGR, a flow rate of said feed stream, and a grinding temperature.

20. The system of claim 19, wherein said controller is coupled to one or more sensors configured to collect one or more signals indicative of a characteristic of said ultramafic material.
